(19) United States
(12) Patent Application Publication
(10) Pub. No.: US 2017/0148747 A1
(43) Pub. Date: May 25, 2017

(54) STRESS RELIEF IN SEMICONDUCTOR WAFERS

(71) Applicant: II-VI OptoElectronic Devices, Inc., Warren, NJ (US)

(72) Inventors: Kevin Chi-Wen Chang, Princeton Junction, NJ (US); Wojciech Krystek, Warren, NJ (US); Douglas Dopp, Annandale, NJ (US); David Hensley, Fanwood, NJ (US); William Wilkinson, Easton, PA (US)

(21) Appl. No.: 15/253,373

(22) Filed: Aug. 31, 2016

Related U.S. Application Data
(60) Provisional application No. 62/187,752, filed on Jul. 1, 2015.

(51) Int. Cl. H01L 23/00; H01L 21/02

(52) U.S. Cl. CPC H01L 23/562; H01L 21/02505; H01L 21/02513

(57) ABSTRACT

Methods for compensating for warpage in a semiconductor structure comprising an epitaxial layer grown on a semiconductor substrate. The methods include forming a buffer layer on the epitaxial layer and forming a compensating layer on the buffer layer; forming a buffer layer on the semiconductor substrate and forming a compensating layer on the buffer layer; and forming grooves in the epitaxial layer.

### CROSS-REFERENCE TO RELATED APPLICATIONS

This application claims the benefit of U.S. Provisional Patent Application No. 62/187,752, filed Jul. 1, 2015, the entire contents of which are incorporated herein by reference.

### BACKGROUND

Warpage in a semiconductor wafer is a constant concern. Warpage can make it difficult, if not impossible, to process the wafer in automated machinery, can move the surface of the wafer out of the image plane required in certain optical processes, and is generally undesirable. As wafer sizes increase, these problems are exacerbated.

One type of semiconductor device that has a significant warpage problem is a vertical cavity surface emitting laser (VCSEL). VCSELs are typically formed by growing a large number of epitaxial layers of a semiconductor material on the surface of a semiconductor wafer. Small differences between the structure of the epitaxial layers and the underlying wafer create stresses that tend to warp the wafer. All the usual problems in processing warped semiconductor wafers can result.

### SUMMARY

In a first illustrative embodiment, warpage in a semiconductor structure comprising an epitaxial layer grown on a semiconductor substrate is compensated for by forming a buffer layer on the epitaxial layer and forming a compensating layer on the buffer layer. The compensating layer stresses the wafer in opposition to the stresses imposed by the epitaxial layer, thereby reducing the warpage in the wafer.

In a second illustrative embodiment, warpage in a semiconductor structure comprising an epitaxial layer grown on a semiconductor substrate is compensated for by forming a buffer layer on the semiconductor substrate and forming a compensating layer on the buffer layer. The compensating layer stresses the wafer in opposition to the stresses imposed by the epitaxial layer, thereby reducing the warpage in the wafer.

In a third illustrative embodiment, warpage in a semiconductor structure comprising an epitaxial layer grown on a semiconductor substrate is compensated for by forming grooves in the epitaxial layer. The grooves relieve the stresses created by the epitaxial layer, thereby reducing the warpage in the wafer.

### BRIEF DESCRIPTION OF THE DRAWINGS

These and other objects, features and advantages of the invention will be more readily apparent from the following detailed description in which:

FIGS. 1A and 1B are a side view and a top view of a warped semiconductor wafer;

FIG. 2 depicts a first illustrative embodiment of the present invention;

FIG. 3 depicts a second illustrative embodiment of the invention;

FIG. 4 depicts a third illustrative embodiment of the invention;

FIG. 5 depicts a fourth illustrative embodiment of the invention;

FIG. 6 depicts a fifth illustrative embodiment of the invention; and

FIG. 7 depicts a sixth illustrative embodiment of the invention.

### DETAILED DESCRIPTION

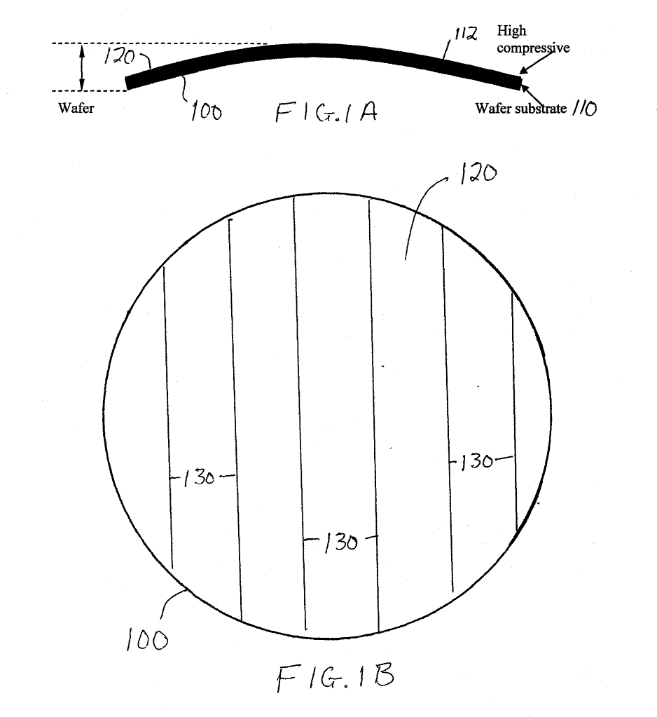

FIGS. 1A and 1B depict a warped semiconductor wafer 100 comprising a semiconductor substrate 110 on one surface 112 of which is grown an epitaxial layer 120 of a semiconductor, typically the same semiconductor material as that of the substrate. The invention may be practiced with any type of semiconductor material. Illustrative examples include silicon, germanium, silicon germanium, silicon carbide, gallium arsenide, gallium nitride, and numerous other semiconductors including binary, tertiary and quaternary compounds.

Because of slight differences in the crystalline structure of the epitaxial layer and that of the substrate, the wafer is stressed causing it to warp. In this case a substantial bow is developed as is apparent in the side view of FIG. 1A. This bow is corrected by the embodiments of FIGS. 2-4.

FIG. 1B is a top view of wafer 100 with several contour lines 130 depicting points having the same deviation above or below a reference plane. The warpage of a wafer is typically characterized in terms of the difference between the maximum deviations above and below the reference plane where the deviations have opposite signs.

In accordance with a first illustrative embodiment of the invention, the warpage in wafer 100 is compensated for by forming a buffer layer 240 on epitaxial layer 120 and forming a compensating layer 250 on the buffer layer as shown in FIG. 2. Buffer layer 240 provides good adherence between epitaxial layer 120 and compensating layer 250. Compensating layer 250 stresses the wafer in opposition to the stresses imposed by epitaxial layer 120, thereby reducing the warpage in the wafer as shown in FIG. 2. Illustratively, epitaxial layer 120 has compressive stress and compensating layer 250 has tensile stress. Alternatively, epitaxial layer 120 may have tensile stress and compensating layer 250 has compressive stress.

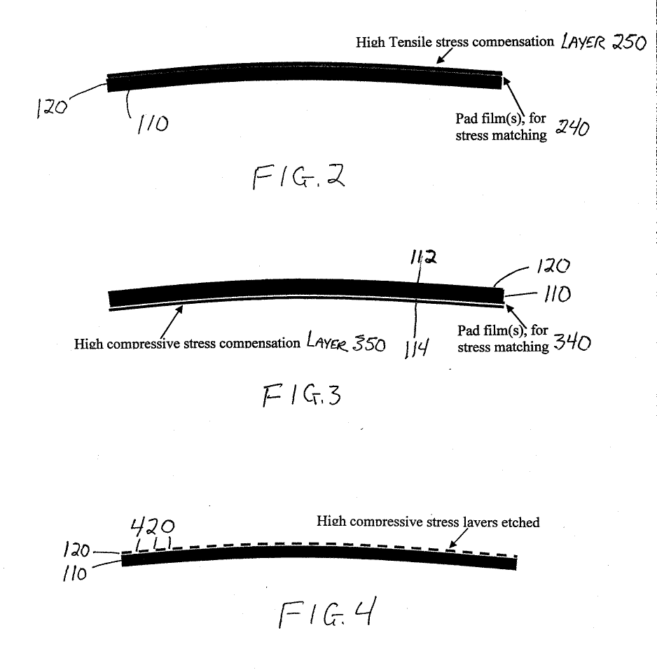

In accordance with a second illustrative embodiment of the invention, the warpage in wafer 100 is compensated for by forming a buffer layer 340 on a second major surface 114 of substrate 110 and forming a compensating layer 350 on the buffer layer as shown in FIG. 3. Thus, compensating layer is on the side of the substrate opposite epitaxial layer 120. Buffer layer 340 provides good adherence between substrate 110 and compensating layer 350. Compensating layer 350 stresses the wafer in opposition to the stresses imposed by epitaxial layer 120, thereby reducing the warpage in the wafer as shown in FIG. 3. Illustratively, both epitaxial layer 120 and compensating layer 350 have compressive stress or both layers have tensile stress.

In accordance with a third illustrative embodiment of the invention, the warpage is compensated for by forming grooves 420 in epitaxial layer 120. The grooves relieve the stresses created by the epitaxial layer, thereby reducing the warpage in the wafer as shown in FIG. 4. In some embodiments, grooves 420 may be formed in epitaxial layer 120 along the lines where the wafer will subsequently be scribed so as to separate (or singulate) the wafer into separate semiconductor devices. In other embodiments, grooves 420 may be formed substantially parallel to some of contour lines representing constant deviation of the surface of the wafer from a reference plane. Optionally, the grooves may be combined with the structures of FIG. 2 or 3.

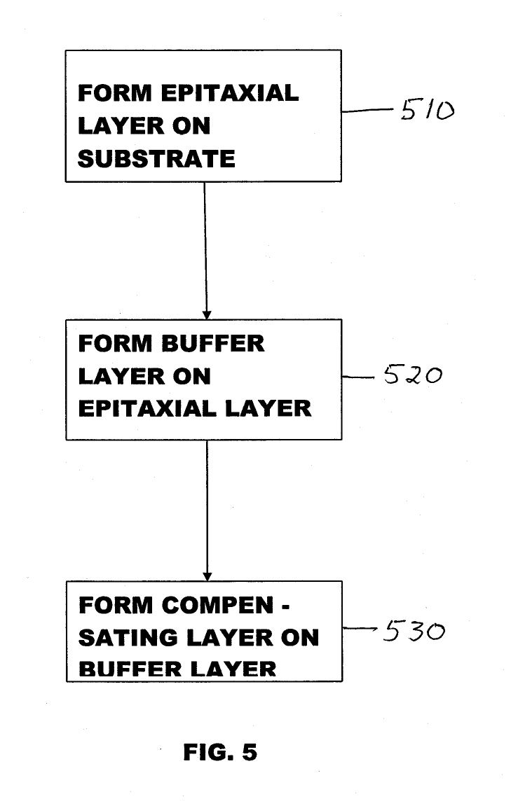

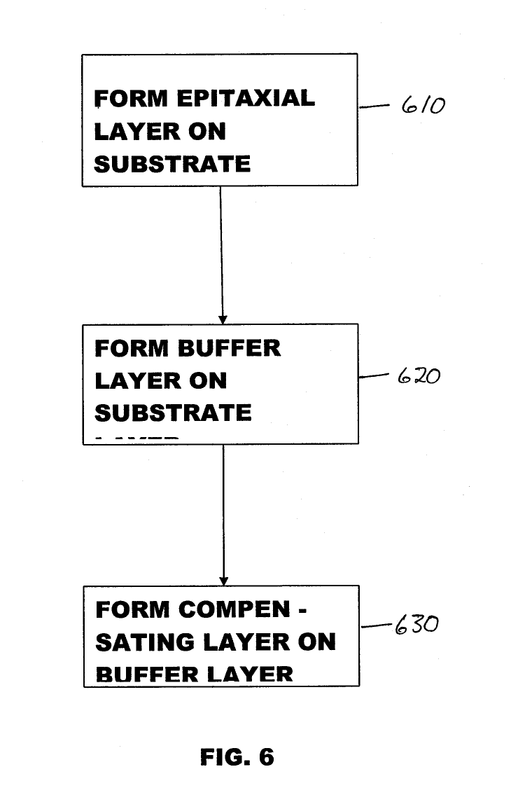

FIG. 5 is a flow chart depicting an illustrative method for practicing the invention. At step 510, an epitaxial layer is formed on a first major surface of a semiconductor wafer. At step 520, a buffer layer is formed on the epitaxial layer. And at step 530, a compensating layer is formed on the buffer layer.

FIG. 6 is a flow chart depicting a second illustrative method for practicing the invention. At step 610, an epitaxial layer is formed on a first major surface of a semiconductor wafer. At step 620, a buffer layer is formed on a second major surface of the semiconductor wafer. And at step 630, a compensating layer is formed on the buffer layer.

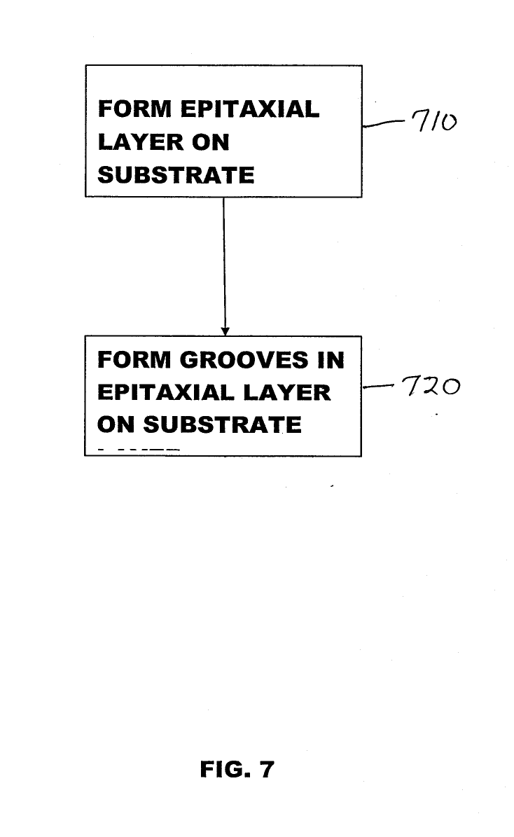

FIG. 7 is a flow chart depicting an illustrative method for practicing the invention. At step 710, an epitaxial layer is formed on a first major surface of a semiconductor wafer. At step 720, grooves are formed in the epitaxial layer.

Optionally, grooves may also be formed in the surface of the epitaxial layer in the processes of FIGS. 5 and 6.

Optionally, wafer warpage may also be reduced by making the wafer thicker than normal. For example, in present day technologies, many wafers are formed that are approximately 675 microns (μ) thick. To reduce warpage, wafers may be formed that are thicker by 20 percent, 40 percent, or even more. Thus, wafers that are 1 millimeter (mm.) thick may also be used to reduce warpage.

As will be apparent to those skilled in the art, numerous variations may be practiced within the spirit and scope of the present invention.

What is claimed is:

1) A semiconductor wafer comprising:
a substrate of a semiconductor material having first and second major surfaces;
an epitaxial layer formed on the first surface of the substrate;
a buffer layer formed on the epitaxial layer; and
a compensating layer formed on the buffer layer and compensating for warpage in the epitaxial layer.

2) The semiconductor wafer of claim 1 wherein grooves are formed in the epitaxial layer to reduce its warpage.

3) The semiconductor wafer of claim 2 wherein the grooves are substantially parallel and aligned with the contours of the warpage.

4) The semiconductor wafer of claim 1 wherein one of the epitaxial layer and the compensating layer has compressive stress and the other has tensile stress.

5) A semiconductor wafer comprising:
a substrate of a semiconductor material having first and second major surfaces;
an epitaxial layer formed on the first surface of the substrate;
a buffer layer formed on the second surface of the substrate; and
a compensating layer formed on the buffer layer and compensating for warpage in the epitaxial layer.

6) The semiconductor wafer of claim 5 wherein grooves are formed in the epitaxial layer to reduce its warpage.

7) The semiconductor wafer of claim 6 wherein the grooves are substantially parallel and aligned with the contours of the warpage.

8) The semiconductor wafer of claim 5 wherein both the epitaxial layer and the compensating layer have compressive stress or both layers have tensile stress.

9) A semiconductor wafer comprising:
a substrate of a semiconductor material having first and second major surfaces;
an epitaxiaxial layer formed on the first surface of the substrate; and
grooves in the epitaxial layer.

10) A method for compensating for warpage in a semiconductor wafer comprising:
forming an epitaxial layer on a first major surface of a semiconductor wafer;
forming a buffer layer on the epitaxial layer;
forming a compensating layer on the buffer layer, the compensating layer compensating for warpage in the epitaxial layer.

11) The method of claim 10 further comprising forming grooves in the epitaxial layer.

12) The method of claim 10 wherein one of the epitaxial layer and the compensating layer has compressive stress and the other has tensile stress

13) A method for compensating for warpage in a semiconductor wafer comprising:
forming an epitaxial layer on a first major surface of a semiconductor wafer;
forming a buffer layer on a second major surface of the semiconductor wafer;
forming a compensating layer on the buffer layer, the compensating layer compensating for warpage in the epitaxial layer.

14) The method of claim 13 further comprising forming grooves in the epitaxial layer.

15) The method of claim 13 wherein both the epitaxial layer and the compensating layer have compressive stress or both layers have tensile stress.

16) A method for compensating for warpage in a semiconductor wafer comprising:
forming an epitaxial layer on a first major surface of a semiconductor wafer;
forming a buffer layer on the epitaxial layer;
forming grooves in the epitaxial layer.

17) The method of claim 16 wherein the grooves are substantially parallel.
